(19) United States
(12) Patent Application Publication
(10) Pub. No.: US 2025/0268075 A1
(43) Pub. Date: Aug. 21, 2025

(54) Display Apparatus Having an Emission Area and a Transparent Area

(71) Applicant: LG Display Co., Ltd., Seoul (KR)

(72) Inventors: Dong Yeon Kim, Paju-si (KR); Hee Cheol Kim, Paju-si (KR); Ju Hoon Jang, Paju-si (KR); Myung Soo Park, Paju-si (KR); Gyu Suk Jung, Paju-si (KR); Gyo Hyun Koo, Paju-si (KR)

(21) Appl. No.: 18/924,743

(22) Filed: Oct. 23, 2024

(30) Foreign Application Priority Data
Feb. 21, 2024 (KR) 10-2024-0024976

(51) Int. Cl. H10K 59/80; G02C 7/02; G06F 1/16; H10K 59/38

(52) U.S. Cl. CPC H10K 59/879; G06F 1/163; H10K 59/38; H10K 59/873; G02C 7/02

(57) ABSTRACT

A display apparatus including emission areas and transparent areas is provided. Light-emitting devices are on the emission areas of a device substrate. The transparent areas of the device substrate are spaced apart from the light-emitting devices. For example, an object located on a rear surface of the display apparatus is recognized by a user disposed on a front surface of the display apparatus through the transparent areas of the device substrate. At least one optical lens can be between the light-emitting devices and the user. Corrective lenses can be between the transparent areas of the device substrate and the at least one optical lens. Each of the corrective lenses can include a curved surface having a different shape from the at least one optical lens. Thus, in the display apparatus, the shape of the objects recognized by the user through the transparent areas of the device substrate are not distorted.

### CROSS-REFERENCE TO RELATED APPLICATION

This application claims the benefit of Republic of Korea Patent Application No. 10-2024-0024976, filed on Feb. 21, 2024, which is hereby incorporated by reference in its entirety.

### BACKGROUND

### Field of Technology

The present disclosure relates to a display apparatus in which a device substrate includes emission areas and transparent areas.

### Discussion of the Related Art

Generally, a display apparatus provides an image to a user. For example, the display apparatus can include a plurality of light-emitting devices. Each of the light-emitting devices can emit light displaying a specific color. For example, each of the light-emitting devices can include a light-emitting layer disposed between a first electrode and a second electrode.

At least one optical lens can be disposed on the light-emitting devices. Light emitted from each light-emitting device can be provided to the user through the at least one optical lens. Thus, the display apparatus can provide the image of various shapes to the user. For example, the display apparatus can provide a three-dimensional image to the user using the at least one optical lens.

The light-emitting devices can be supported by a device substrate. The display apparatus can be a transparent display apparatus. For example, the device substrate can include transparent areas spaced apart from the light-emitting devices. Objects located on a rear surface of the display apparatus can be recognized by a user disposed on a front surface of the display apparatus through the transparent areas of the device substrate. However, in the display apparatus, external light passing through the transparent areas can be refracted by the at least one optical lens. Thus, in the display apparatus, the shape of the objects recognized by the user through the transparent areas of the devices can be distorted.

### SUMMARY

Accordingly, the present disclosure is directed to a display apparatus that substantially obviates one or more problems due to limitations and disadvantages of the related art.

An object of the present disclosure is to provide a display apparatus capable of preventing the distortion of the objects recognized by the user through the transparent areas of the device substrate.

Another object of the present disclosure is to provide a display apparatus capable of correcting the external light refracted by the at least one optical lens.

Additional advantages, objects, and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus comprising a device substrate. The device substrate includes an emission area and a transparent area. A light-emitting device is disposed on the emission area of the device substrate. A corrective lens overlaps the transparent area of the device substrate. At least one optical lens is disposed on the light-emitting device and the corrective lens. A surface of the corrective lens opposite to the at least one optical lens has a concave curved shape.

A surface of the at least one optical lens opposite to the device substrate can have a convex curved shape.

The device substrate includes a first surface and a second surface. The light-emitting device can be disposed on the first surface of the device substrate. The corrective lens can be disposed on the second surface of the device substrate. The second surface can be opposite to the first surface.

A surface of the corrective lens toward the at least one optical lens can be in contact with the second surface of the device substrate.

A filter insulating layer can be disposed between the light-emitting device and the at least one optical lens. The filter insulating layer can extend onto the transparent area of the device substrate. A color filter can be disposed between the light-emitting device and the filter insulating layer. The color filter can overlap the emission area. The at least one optical lens can be in contact with the filter insulating layer.

The at least one optical lens can include a first lens region and a second lens region. The first lens region can overlap the emission area. The second lens region can overlap the transparent area. A width of the second lens region can be the same as a width of the first lens region.

In another embodiment, there is provided a display apparatus comprising a device substrate. The device substrate includes a plurality of pixel areas. Light-emitting devices and a correction structure are disposed on the device substrate. Each of the light-emitting devices is disposed on an emission area of each pixel area. The correction structure includes curved surfaces of a concave shape overlapping the transparent area of each pixel area. At least one optical lens is disposed on the light-emitting devices and the correction structure. The correction structure includes a first surface toward the at least one optical lens and a second surface opposite to the first surface. The curved surfaces of a concave shape are disposed at the second surface of the correction structure.

A surface of the at least one optical lens can have a curved surface of a convex shape. The curved surface of a convex shape can have a different curvature from the curved surface of a concave shape.

An encapsulation structure can be disposed on the device substrate. The encapsulation structure can cover the light-emitting devices. The correction structure can be disposed between the encapsulation structure and the at least one optical lens.

The correction structure can extend onto the emission area of each pixel area.

Corrective patterns can be disposed between the encapsulation structure and the correction structure. The corrective patterns can be contact with the curved surfaces of a concave shape. A refractive index of each corrective pattern can be smaller than a refractive index of the correction structure.

A surface of each corrective pattern toward the encapsulation structure can be continuously with a surface of the correction structure toward the encapsulation structure.

Pixel lenses can be disposed between the encapsulation structure and the correction structure. Each of the pixel lenses can overlap the emission area of each pixel area. A surface of each pixel lens toward the at least one optical lens can have a curved surface of a convex shape.

The surface of each pixel area toward the at least one optical lens can be in contact with the correction structure. A refractive index of the correction structure can be smaller than a refractive index of each pixel lens.

A surface of each pixel lens toward the encapsulation structure can be continuously with a surface of the correction structure toward the encapsulation structure.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is an enlarged view of K1 region in FIG. 1 according to an embodiment of the present disclosure;

FIG. 3 is a view showing a circuit of a sub-pixel in the display apparatus according to an embodiment of the present disclosure;

FIG. 4 is a view taken along I-I′ of FIG. 2 according to an embodiment of the present disclosure;

FIGS. 5 to 10 are views showing the display apparatus according to other embodiments of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

In addition, the same or extremely similar elements can be designated by the same reference numerals throughout the specification and in the drawings, the lengths and thickness of layers and regions can be exaggerated for convenience. It will be understood that, when a first element is referred to as being “on” a second element, although the first element can be disposed on the second element so as to come into contact with the second element, a third element can be interposed between the first element and the second element.

Here, terms such as, for example, “first” and “second” can be used to distinguish any one element with another element. However, the first element and the second element can be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” can include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

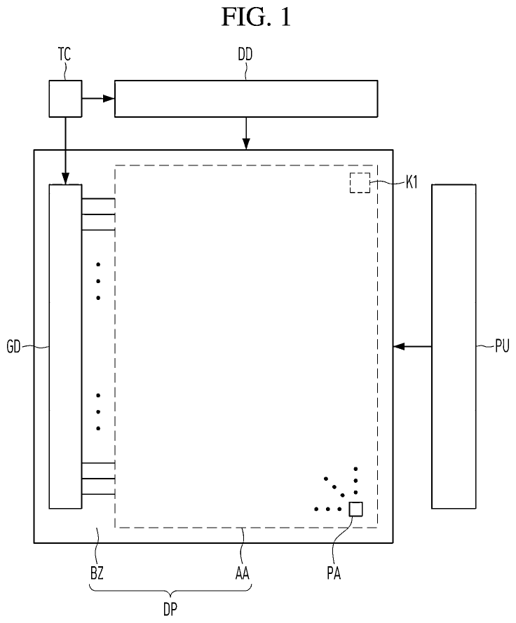

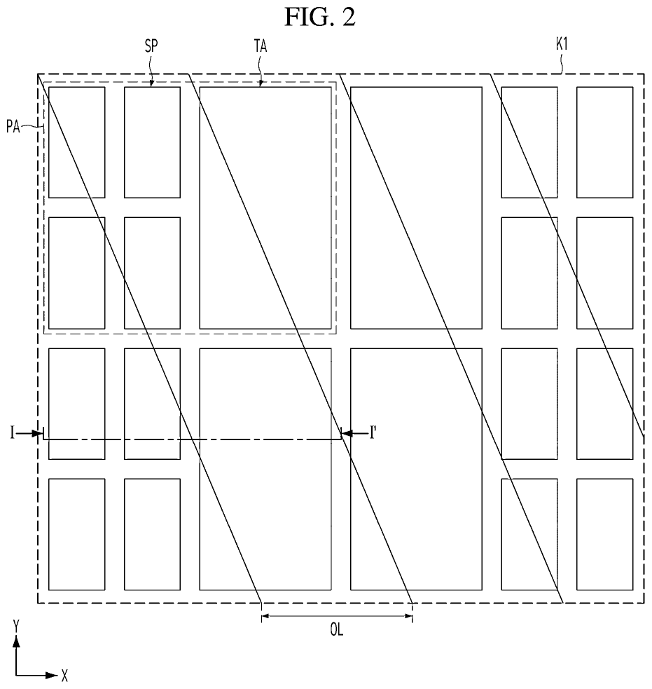

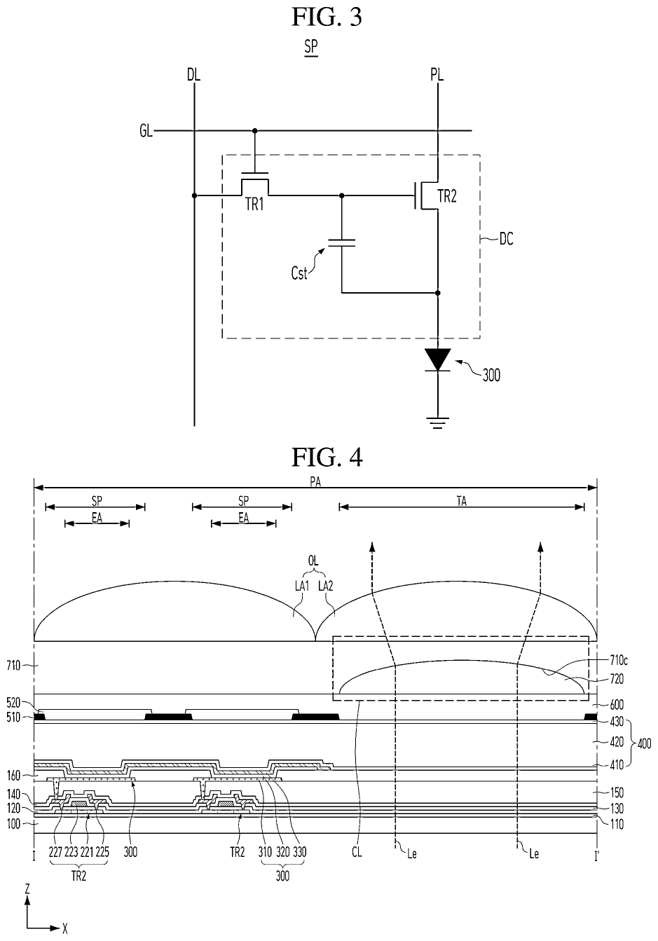

FIG. 1 is a view schematically showing a display apparatus according to an embodiment of the present disclosure. FIG. 2 is an enlarged view of Kl region in FIG. 1 according to an embodiment of the present disclosure. FIG. 3 is a view showing a circuit of a sub-pixel in the display apparatus according to the embodiment of the present disclosure. FIG. 4 is a view taken along I-I′ of FIG. 2 according to an embodiment of the present disclosure.

Referring to FIGS. 1 to 4, the display apparatus according to the embodiment of the present disclosure can include a display panel DP. The display panel DP can generate an image provided to a user. For example, a plurality of pixel areas PA can be disposed in the display panel DP. Each of the pixel areas PA can realize various colors. For example, each of the pixel areas PA can include a plurality of sub-pixels SP. Various signals can be provided in each sub-pixel SP through signal wirings GL, DL and PL. For example, the signal wirings GL, DL and PL can include gate lines GL applying a gate signal, data lines DL applying a data signal, and power voltage supply lines PL supplying a power voltage.

The gate lines GL can be electrically connected to a gate driver GD. The data lines DL can be electrically connected to a data driver DD. The gate driver GD and the data driver DD can be controlled by a timing controller TC. For example, the gate driver GD can receive clock signals, reset signals and a start signal from the timing controller TC, and the data driver DD can receive digital video data and a source timing signal from the timing controller TC. The power voltage supply lines PL can be electrically connected to a power unit PU.

The display panel DP can include an active area AA in which the pixel areas PA are disposed, and a bezel area BZ being disposed outside the active area AA. The bezel area BZ can be disposed outside the pixel areas PA. For example, the active area AA can be surrounded by the bezel area BZ. The gate driver GD, the data driver DD, the timing controller TC and the power unit PU can be disposed outside the active area AA. For example, each of the signal wirings GL, DL and PL can include a region disposed on the bezel area BZ.

At least one of the gate driver GD, the data driver DD, the timing controller TC and the power unit PU can be disposed on the bezel area BZ. For example, the display apparatus according to the embodiment of the present disclosure can be a GIP (Gate In Panel) type display apparatus in which the gate driver GD is formed on the bezel area BZ.

Each of the sub-pixels SP can display a specific color. For example, a driving circuit DC electrically connected to a light-emitting device 300 can be disposed in each sub-pixel SP. The driving circuit DC of each sub-pixel SP can control the light-emitting device 300 of the corresponding sub-pixel SP according to signals applied to the signal wirings GL, DL and PL. For example, the driving circuit DC of each sub-pixel SP can supply a driving current corresponding to the data signal to the light-emitting device 300 of the corresponding sub-pixel SP according to the gate signal. The driving current supplied by the driving circuit DC of each sub-pixel SP can be maintained for one frame. For example, the driving circuit DC of each sub-pixel SP can include a first thin film transistor TR1, a second thin film transistor TR2 and a storage capacitor Cst.

The first thin film transistor TR1 of each sub-pixel SP can transmit the data signal to the second thin film transistor TR2 of the corresponding sub-pixel SP according to the gate signal. For example, the first thin film transistor TR1 of each sub-pixel SP can function as a switching thin film transistor. The first thin film transistor TR1 of each sub-pixel SP can include a first semiconductor pattern, a first gate electrode, a first drain electrode and a first source electrode. For example, the first gate electrode of each sub-pixel SP can be electrically connected to the corresponding gate line GL, and the first drain electrode of each sub-pixel SP can be electrically connected to the corresponding date line DL.

The first semiconductor pattern can include a semiconductor material. For example, the first semiconductor pattern can include Low-Temperature Poly-Si (LTPS) or an oxide semiconductor, such as IGZO. The first semiconductor pattern can include a first drain region, a first channel region and a first source region. The first channel region can be disposed between the first drain region and the first source region. The first drain region and the first source region can have a resistance smaller than the first channel region. For example, the first drain region and the first source region can include a conductive region of an oxide semiconductor. The first channel region can be a region of an oxide semiconductor, which is not conductorized.

The first gate electrode can be disposed on a portion of the first semiconductor pattern. For example, the first gate electrode can overlap the first channel region of the first semiconductor pattern. The first drain region and the first source region of the first semiconductor pattern can be disposed outside the first gate electrode. The first gate electrode can include a conductive material. For example, the first gate electrode can include a metal, such as aluminum (Al), chrome (Cr), copper (Cu), molybdenum (Mo), titanium (Ti) and tungsten (W). The first gate electrode can be spaced apart from the first semiconductor pattern. The first gate electrode can be insulated from the first semiconductor pattern. For example, the first drain region of the first semiconductor pattern can be electrically connected to the first source region of the first semiconductor pattern according to a signal applied to the first gate electrode.

The first drain electrode can include a conductive material. For example, the first drain electrode can include a metal, such as aluminum (Al), chrome (Cr), copper (Cu), molybdenum (Mo), titanium (Ti) and tungsten (W). The first drain electrode can include a different material from the first gate electrode. For example, the first drain electrode can be disposed on a different layer from the first gate electrode. The first drain electrode can be electrically connected to the first drain region of the first semiconductor pattern. The first drain electrode can be insulated from the first gate electrode.

The first source electrode can include a conductive material. For example, the first source electrode can include a metal, such as aluminum (Al), chrome (Cr), copper (Cu), molybdenum (Mo), titanium (Ti) and tungsten (W). The first source electrode can include a different material from the first gate electrode. The first source electrode can be disposed on a different layer from the first gate electrode. For example, the first source electrode can be disposed on a same layer as the first drain electrode. The first source electrode can include a same material as the first drain electrode. The first source electrode can be formed by a same process as the first drain electrode. For example, the first source electrode can be formed simultaneously with the first drain electrode. The first source electrode can be electrically connected to the first source region of the first semiconductor pattern. The first source electrode can be insulated from the first gate electrode.

The second thin film transistor TR2 of each sub-pixel SP can generate the driving current corresponding to the data signal. For example, the second thin film transistor TR2 of each sub-pixel SP can function as a driving thin film transistor. The second thin film transistor TR2 of each sub-pixel SP can include a second semiconductor pattern 221, a second gate electrode 223, a second drain electrode 225 and a second source electrode 227. For example, the second gate electrode 223 of each sub-pixel SP can be electrically connected to the first source electrode of the corresponding sub-pixel SP, and the second drain electrode 225 of each sub-pixel SP can be electrically connected to the corresponding power voltage supply line PL.

The second semiconductor pattern 221 can include a semiconductor material. For example, the second semiconductor pattern 221 can include Low-Temperature Poly-Si (LTPS) or an oxide semiconductor, such as IGZO. The second semiconductor pattern 221 can include a same material as the first semiconductor pattern. The second semiconductor pattern 221 can be disposed on a same layer as the first semiconductor pattern. The second semiconductor pattern 221 can be formed by a same process as the first semiconductor pattern. For example, the second semiconductor pattern 221 can be formed simultaneously with the first semiconductor pattern.

The second semiconductor pattern 221 can include a second drain region, a second channel region and a second source region. The second channel region can be disposed between the second drain region and the second source region. The second drain region and the second source region can have a resistance smaller than the second channel region. For example, the second drain region and the second source region can include a conductive region of an oxide semiconductor. The second channel region can be a region of an oxide semiconductor, which is not conductorized.

The second gate electrode 223 can be disposed on a portion of the second semiconductor pattern 221. For example, the second gate electrode 223 can overlap the second channel region of the second semiconductor pattern 221. The second drain region and the second source region of the second semiconductor pattern 221 can be disposed outside the second gate electrode 223. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be spaced apart from the second semiconductor pattern 221. The second gate electrode 223 can be insulated from the second semiconductor pattern 221. For example, the second channel region of the second semiconductor pattern 221 can have an electrical conductivity corresponding to a voltage applied to the second gate electrode 223.

The second gate electrode 223 can include a same material as the first gate electrode. The second gate electrode 223 can be disposed on a same layer as the first gate electrode. The second gate electrode 223 can be formed by a same process as the first gate electrode. For example, the second gate electrode 223 can be formed simultaneously with the first gate electrode.

The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can include a different material from the second gate electrode 223. For example, the second drain electrode 225 can be disposed on a different layer from the second gate electrode 223. The second drain electrode 225 can be electrically connected to the second drain region of the second semiconductor pattern 221. The second drain electrode 225 can be insulated from the second gate electrode 223.

The second drain electrode 225 can be disposed on a same layer as the first drain electrode. The second drain electrode 225 can include a same material as the first drain electrode. The second drain electrode 225 can be formed by a same process as the first drain electrode. For example, the second drain electrode 225 can be formed simultaneously with the first drain electrode.

The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can include a different material from the second gate electrode 223. The second source electrode 227 can be disposed on a different layer from the second gate electrode 223. For example, the second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225.

The second source electrode 227 can be electrically connected to the second source region of the second semiconductor pattern 221. The second source electrode 227 can be insulated from the second gate electrode 223. The second source electrode 227 can be spaced apart from the second drain electrode 225.

The storage capacitor Cst of each sub-pixel SP can maintain a voltage applied to the second gate electrode 223 of the corresponding sub-pixel SP for one frame. For example, the storage capacitor Cst of each sub-pixel SP can be electrically connected to the second gate electrode 223 and the second source electrode 227 of the corresponding sub-pixel SP. The storage capacitor Cst of each sub-pixel SP can have a stacked structure of capacitor electrodes. For example, the storage capacitor Cst of each sub-pixel SP can include a first capacitor electrode electrically connected to the second gate electrode 233 of the corresponding sub-pixel SP, and a second capacitor electrode electrically connected to the second source electrode 227 of the corresponding sub-pixel SP.

The storage capacitor Cst of each sub-pixel SP can be formed by using a process of forming the first thin film transistor TR1 and the second thin film transistor TR2 in the corresponding sub-pixel SP. For example, the first capacitor electrode of each sub-pixel SP can be disposed on a same layer as the second gate electrode 223 of the corresponding sub-pixel SP, and the second capacitor electrode of each sub-pixel SP can be disposed on a same layer as the second source electrode 227 of the corresponding sub-pixel SP. The first capacitor electrode of each sub-pixel SP can include a same material as the second gate electrode 223 of the corresponding sub-pixel SP, and the second capacitor electrode of each sub-pixel SP can include a same material as the second source electrode 227 of the corresponding sub-pixel SP. The first capacitor electrode of each sub-pixel SP can be formed by a same process as the second gate electrode 223 of the corresponding sub-pixel SP, and the second capacitor electrode of each sub-pixel SP can be formed by a same process as the second source electrode 227 of the corresponding sub-pixel SP. For example, the first capacitor electrode of each sub-pixel SP can be formed simultaneously with the second gate electrode 223 of the corresponding sub-pixel SP, and the second capacitor electrode of each sub-pixel SP can be formed simultaneously with the second source electrode 227 of the corresponding sub-pixel SP. Thus, in the display apparatus according to the embodiment of the present disclosure, a process of forming the driving circuit DC in each sub-pixel SP can be simplified.

The light-emitting device 300 and the driving circuit DC of each sub-pixel SP can be disposed on a device substrate 100. For example, the device substrate 100 can support the light-emitting device 300 and the driving circuit DC of each sub-pixel SP. The device substrate 100 can include an insulating material. For example, the device substrate 100 can include glass or plastic.

A plurality of insulating layers 110, 120, 130, 140, 150 and 160 for preventing or at least reducing unnecessary electrical connection can be disposed on the device substrate 100. For example, a buffer insulating layer 110, a gate insulating layer 120, an interlayer insulating layer 130, a device passivation layer 140, a planarization layer 150 and a bank insulating layer 160 can be disposed on the device substrate 100.

The buffer insulating layer 110 can be disposed on the device substrate 100. The buffer insulating layer 110 can prevent or at least reduce the pollution due to the device substrate 100 in a process of forming the driving circuit DC in each sub-pixel SP. For example, an upper surface of the device substrate 100 toward the driving circuit DC of each sub-pixel SP can be completely covered by the buffer insulating layer 110. The buffer insulating layer 110 can include an insulating material. For example, the buffer insulating layer 110 can include an inorganic insulating material, such as silicon oxide (SiOx) and silicon nitride (SiNx). The buffer insulating layer 110 can have a multi-layer structure. For example, the buffer insulating layer 110 can have a structure in which an inorganic insulating layer made of silicon oxide (SiOx) and an inorganic insulating layer made of silicon nitride (SiNx) are stacked.

The gate insulating layer 120 can be disposed on the buffer insulating layer 110. The first gate electrode of each sub-pixel SP can be insulated from the first semiconductor pattern of the corresponding sub-pixel SP by the gate insulating layer 120. The second gate electrode 223 of each sub-pixel SP can be insulated from the second semiconductor pattern 221 of the corresponding sub-pixel SP by the gate insulating layer 120. For example, the gate insulating layer 120 can cover the first semiconductor pattern and the second semiconductor pattern 221 of each sub-pixel SP. The first gate electrode and the second gate electrode 223 of each sub-pixel SP can be disposed on the gate insulating layer 120. The gate insulating layer 120 can include an insulating material. For example, the gate insulating layer 120 can include an inorganic insulating material, such as silicon oxide (SiOx) and silicon nitride (SiNx).

The interlayer insulating layer 130 can be disposed on the gate insulating layer 120. The first drain electrode and the first source electrode of each sub-pixel SP can be insulated from the first gate electrode of the corresponding sub-pixel SP by the interlayer insulating layer 130. The second drain electrode 225 and the second source electrode 227 of each sub-pixel SP can be insulated from the second gate electrode 223 of the corresponding sub-pixel SP by the interlayer insulating layer 130. For example, the interlayer insulating layer 130 can cover the first gate electrode and the second gate electrode 223 of each sub-pixel SP. The first drain electrode, the first source electrode, the second drain electrode 225 and the second source electrode 227 of each sub-pixel SP can be disposed on the interlayer insulating layer 130. The interlayer insulating layer 130 can include an insulating material. For example, the interlayer insulating layer 130 can include an inorganic insulating material.

The device passivation layer 140 can be disposed on the interlayer insulating layer 130. The device passivation layer 140 can prevent or at least reduce the damage of the driving circuit DC in each sub-pixel SP due to the external impact and moisture. The device passivation layer 140 can extend beyond the driving circuit DC in each sub-pixel SP. The device passivation layer 140 can extend along an upper surface of the driving circuit DC of each sub-pixel SP opposite to the device substrate 100. For example, the first drain electrode, the first source electrode, the second drain electrode 225 and the second source electrode 227 of each sub-pixel SP can be covered by the device passivation layer 140. The device passivation layer 140 can extend beyond the driving circuit DC in each pixel area PA. The device passivation layer 140 can include an insulating material. For example, the device passivation layer 140 can be a linear insulating layer made of an inorganic insulating material.

The planarization layer 150 can be disposed on the device passivation layer 140. The planarization layer 150 can remove a thickness difference due to the driving circuit DC of each sub-pixel SP. For example, an upper surface of the planarization layer 150 opposite to the device substrate 100 can be a flat surface. The upper surface of the planarization layer 150 can be parallel to the upper surface of the device substrate 100. The planarization layer 150 can include an insulating material. The planarization layer 150 can include a different material from the device passivation layer 140. The planarization layer 150 can include a material having a relatively high fluidity. For example, the planarization layer 150 can include an organic insulating material.

The light-emitting device 300 of each sub-pixel SP can be disposed on the planarization layer 150. The light-emitting device 300 of each sub-pixel SP can emit light displaying a specific color. For example, the light-emitting device 300 of each sub-pixel SP can include a first electrode 310, a light-emitting layer 320, and a second electrode 330, which are sequentially stacked on the planarization layer 150 of the corresponding sub-pixel SP.

The first electrode 310 can include a conductive material. The first electrode 310 can include a material having a relatively high reflectance. For example, the first electrode 310 can include a metal, such as aluminum (Al) and silver (Ag). The first electrode 310 can have a multi-layer structure. For example, the first electrode 310 can have a structure in which a reflective electrode made of a metal is disposed between transparent electrodes made of a transparent conductive material, such as ITO and IZO.

The light-emitting layer 320 can generate light having luminance corresponding to a voltage difference between the first electrode 310 and the second electrode 330. For example, the light-emitting layer 320 can include at least one emission material layer (EML). The emission material layer can include an organic emission material, an inorganic emission material, or a hybrid emission material. For example, the display apparatus according to the embodiment of the present disclosure can be an organic light-emitting display apparatus including an organic emission material.

The light-emitting layer 320 can have a multi-layer structure. For example, the light-emitting layer 320 can include at least one of a hole injection layer (HIL), a hole transport layer (HTL), an electron transport layer (ETL) and an electron injection layer (EIL). Thus, in the display apparatus according to the embodiment of the present disclosure, the emission efficiency of the light-emitting layer 320 can be improved.

The second electrode 330 can include a conductive material. The second electrode 330 can include a different material from the first electrode 310. A transmittance of the second electrode 330 can be greater than a transmittance of the first electrode 310. For example, the second electrode 330 can be a transparent electrode made of a transparent conductive material, such as ITO and IZO. Thus, in the display apparatus according to the embodiment of the present disclosure, the light generated by the light-emitting layer 320 can be emitted through the second electrode 330. The second electrode 330 can have a work-function smaller than the first electrode 310. For example, the first electrode 310 can function as anode electrode, and the second electrode 330 can function as cathode electrode.

The bank insulating layer 160 can be disposed on the planarization layer 150. The bank insulating layer 160 can include an insulating material. For example, the bank insulating layer 160 can include an organic insulating material. The bank insulating layer 160 can include a different material from the planarization layer 150. The bank insulating layer 160 can define an emission area EA in each sub-pixel SP. For example, the first electrode 310 of each sub-pixel SP can be partially exposed by the bank insulating layer 160, and the light-emitting layer 320 and the second electrode 330 of each sub-pixel SP can be stacked on a portion of the corresponding first electrode 310 exposed by the bank insulating layer 160. The first electrode 310 of each sub-pixel SP can be insulated from the first electrode 310 of adjacent sub-pixel SP by the bank insulating layer 160. For example, an edge of the first electrode 310 in each sub-pixel SP can be covered by the bank insulating layer 160.

The first electrode 310 of each sub-pixel SP can be electrically connected to the driving circuit DC of the corresponding sub-pixel SP. For example, the first electrode 310 of each sub-pixel SP can be in direct contact with the second source electrode 227 of the corresponding sub-pixel SP by penetrating the device passivation layer 140 and the planarization layer 150. The electric connection between the second source electrode 227 and the first electrode 310 in each sub-pixel SP can be performed outside the emission area EA defined in the corresponding sub-pixel SP. Thus, in the display apparatus according to the embodiment of the present disclosure, the change in the location of the first electrode 310 in the emission area EA of each sub-pixel SP can be minimized or at least reduced. For example, a portion of the first electrode 310 overlapping with the emission area EA of each sub-pixel SP can extend along the upper surface of the planarization layer 150. A portion of the first electrode 310 overlapping with the emission area EA of each sub-pixel SP can be in direct contact with the upper surface of the planarization layer 150. Therefore, in the display apparatus according to the embodiment of the present disclosure, the luminance deviation according to the generating location of the light emitted from the emission area EA of each sub-pixel SP can be prevented.

The light emitted from the light-emitting device 300 of each sub-pixel SP can display a same color as the light emitted from the light-emitting device 300 of adjacent sub-pixel SP. For example, the light emitted from the light-emitting device 300 of each sub-pixel SP can be white light. The light-emitting layer 320 of each sub-pixel SP can have a stacked structure same as the light-emitting layer 320 of adjacent sub-pixel SP. The light-emitting layer 320 of each sub-pixel SP can be formed by a same process as the light-emitting layer 320 of adjacent sub-pixel SP. For example, the light-emitting layer 320 of each sub-pixel SP can be formed simultaneously with the light-emitting layer 320 of adjacent sub-pixel SP. The light-emitting layer 320 of each sub-pixel SP can be in direct contact with the light-emitting layer 320 of adjacent sub-pixel SP. Thus, in the display apparatus according to the embodiment of the present disclosure, a process of forming the light-emitting layer 320 in each sub-pixel SP can be simplified.

A voltage applied to the second electrode 330 of each sub-pixel SP can be a same as a voltage applied to the second electrode 330 of adjacent sub-pixel SP. For example, the second electrode 330 of each sub-pixel SP can be electrically connected to the second electrode 330 of adjacent sub-pixel SP. The second electrode 330 of each sub-pixel SP can include a same material as the second electrode 330 of adjacent sub-pixel SP. The second electrode 330 of each sub-pixel SP can be formed by a same process as the second electrode of adjacent sub-pixel SP. For example, the second electrode 330 of each sub-pixel SP can be formed simultaneously with the second electrode 330 of adjacent sub-pixel SP. The second electrode 330 of each sub-pixel SP can be in direct contact with the second electrode 330 of adjacent sub-pixel SP. Thus, in the display apparatus according to the embodiment of the present disclosure, a process of forming the second electrode 330 in each sub-pixel SP can be simplified. And, in the display apparatus according to the embodiment of the present disclosure, the luminance of the light generated by the light-emitting layer 320 of each sub-pixel SP can be adjusted by the data signal applied to the driving circuit DC of the corresponding sub-pixel SP.

An encapsulation structure 400 can be disposed on the light-emitting device 300 of each sub-pixel SP. The encapsulation structure 400 can prevent or at least reduce the damage of the light-emitting device 300 in each sub-pixel SP due to the external impact and moisture. The encapsulation structure 400 can have a multi-layer structure. For example, the encapsulation structure 400 can include a first encapsulating layer 410, a second encapsulating layer 420 and a third encapsulating layer 430, which are sequentially stacked. The first encapsulating layer 410, the second encapsulating layer 420 and the third encapsulating layer 430 can include an insulating material. The second encapsulating layer 420 can include a different material from the first encapsulating layer 410 and the third encapsulating layer 430. For example, the first encapsulating layer 410 and the third encapsulating layer 430 can include an inorganic insulating material, and the second encapsulating layer 420 can include an organic insulating material. Thus, in the display apparatus according to the embodiment of the present disclosure, the damage of the light-emitting device 300 in each sub-pixel SP due to the external impact and moisture can be effectively prevented. A thickness difference due to the light-emitting device 300 of each sub-pixel SP can be removed by the second encapsulating layer 420. The second encapsulating layer 420 can have a greater thickness than the first encapsulating layer 410 and the third encapsulating layer 430. For example, an upper surface of the encapsulation structure 400 opposite to the device substrate 100 can be a flat surface. The upper surface of the encapsulation structure 400 can be parallel to the upper surface of the device substrate 100.

The light emitted from the emission area EA of each sub-pixel SP can be different from the light emitted from the emission area EA of adjacent sub-pixel SP. For example, a color filter 520 can be disposed in each sub-pixel SP. The color filter 520 of each sub-pixel SP can be disposed on a path of the light emitted from the light-emitting device 300 of the corresponding sub-pixel SP. For example, the color filter 520 of each sub-pixel SP can be disposed on the encapsulation structure 400. The color filter 520 of each sub-pixel SP can display a specific color by using the light emitted from the light-emitting device 300 of the corresponding sub-pixel SP. For example, the color filter 520 of each sub-pixel SP can be one of a red color filter displaying red color, a green color filter displaying green color, and a blue color filter displaying blue color. The color filter 520 of each sub-pixel SP can include a different material from the color filter 520 of adjacent sub-pixel SP in each pixel area PA. The color of each pixel area PA can be realized by mixing the light emitted from the emission areas EA of the corresponding pixel area PA.

The color filter 520 of each sub-pixel SP can have a greater size than the emission area EA of the corresponding sub-pixel SP. For example, the color filter 520 of each sub-pixel SP can have a greater width than the emission area EA of the corresponding sub-pixel SP in a first direction X. Thus, in the display apparatus according to the embodiment of the present disclosure, the amount of the light that is generated by the light-emitting device 300 of each sub-pixel SP and passes through the color filter 520 of the corresponding sub-pixel SP can be increased. Therefore, in the display apparatus according to the embodiment of the present disclosure, the light extraction efficiency of each sub-pixel SP can be improved.

A black matrix 510 can be disposed between the emission areas EA of each pixel area PA. The black matrix 510 can include a material capable to block light. For example, the black matrix 510 can include a black dye, such as carbon black. The black matrix 510 can limit the travelling direction of the light emitted from the light-emitting device 300 of each sub-pixel SP. For example, the light emitted from the light-emitting device 300 of each sub-pixel SP toward the color filer 520 of adjacent sub-pixel SP can be blocked by the black matrix 510. Thus, in the display apparatus according to the embodiment of the present disclosure, unintentional color mixing can be prevented.

The black matrix 510 can be disposed outside the emission areas EA. For example, the black matrix 510 can overlap the bank insulating layer 160. The black matrix 510 can be disposed side by side with the color filter 520 of each sub-pixel SP. For example, the black matrix 510 can be disposed on the encapsulation structure 400. An end of the color filter 520 on each sub-pixel SP can overlap the black matrix 510. The color filter 520 of each sub-pixel SP and the black matrix 510 can be in direct contact with the third encapsulating layer 430. For example, the color filter 520 in each sub-pixel SP can include a lower surface toward the device substrate 100, and a lower surface of the black matrix 520 toward the device substrate 100 can be continuous with the lower surface of the color filter 520 in each sub-pixel SP. Thus, in the display apparatus according to the embodiment of the present disclosure, the light leakage due to the light passing between the color filter 520 of each sub-pixel SP and the black matrix 510 can be prevented or at least reduced.

A filter insulating layer 600 can be disposed on the black matrix 510 and the color filters 520. The filter insulating layer 600 can prevent or at least reduce the damage of the black matrix 510 and the color filters 520 due to the external impact and moisture. For example, the black matrix 510 and the color filters 520 can be covered by the filter insulating layer 600. The filter insulating layer 600 can include an insulating material. For example, the filter insulating layer 600 can include an organic insulating material and/or an inorganic insulating material. An upper surface of the filter insulating layer 600 opposite to the encapsulation structure 400 can be flat.

A plurality of optical lenses OL can be disposed on the filter insulating layer 600. The light emitted from the emission area EA of each sub-pixel SP can be provided to the user by the optical lenses OL in various ways. For example, in the display apparatus according to the embodiment of the present disclosure, the image realized by the pixel areas PA can be three-dimensionally recognized by the user by the optical lenses OL. Each of the optical lenses OL can include a convex lens. A surface of each optical lens OL toward the device substrate 100 can have a curved surface of a convex shape. For example, the optical lenses OL can be lenticular lenses extending parallel to each other in a direction. The optical lenses OL can be disposed side by side along the upper surface of the filter insulating layer 600. For example, in the display apparatus according to the embodiment of the present disclosure, the sub-pixels SP of each pixel area PA can be disposed side by side in the first direction X and a second direction Y perpendicular to the first direction X, and each of the optical lenses OL can extend in a direction inclined with the first direction X and the second direction Y. The light emitted from the emission area EA of each sub-pixel SP can be provided to the user through one of the optical lenses OL.

Each of the pixel area PA can include a transparent area TA. The external light Le incident through the device substrate 100 can pass through the transparent area TA of each pixel area PA. For example, the transparent area TA of each pixel area PA can be spaced apart from the light-emitting devices 300 in the corresponding pixel area PA. For example, the first electrodes 310, the light-emitting layer 320 and the second electrode 320 in each pixel area PA can't overlap the transparent area TA of the corresponding pixel area PA. Thus, in the display apparatus according to the embodiment of the present disclosure, objects located on a lower surface of the device substrate 100 opposite to the upper surface of the device substrate 100 can be recognized by the user disposed on the upper surface of the device substrate 100 by the external light Le passing through the transparent area TA of each pixel area PA. That is, the display apparatus according to the embodiment of the present disclosure can be a transparent display apparatus. For example, when the light is not emitted from the light-emitting device 300 of each sub-pixel SP, the display apparatus according to the embodiment of the present disclosure can be recognized by the user as a transparent glass. And, in the display apparatus according to the embodiment of the present disclosure, the image by the display panel DP can be provided to the user, without blocking the user's field of view. For example, in the display apparatus according to the embodiment of the present disclosure, the image realized by the display panel DP and the objects located on the lower surface of the device substrate 100 can be simultaneously recognized by the user. Therefore, in the display apparatus according to the embodiment of the present disclosure, the accident due to block the user's field of view can be prevented.

The transparent area TA of each pixel area PA can be disposed side by side with the sub-pixels SP of the corresponding pixel area PA. For example, the transparent area TA of each pixel area PA can be disposed side by side with the sub-pixels SP of the corresponding pixel area PA in the first direction X. The transparent area TA of each pixel area PA can have a greater size than each sub-pixel SP in the corresponding pixel area PA. For example, the transparent area TA of each pixel area PA can have a greater length than each sub-pixel SP of the corresponding pixel area PA in the first direction X and the second direction Y. Thus, in the display apparatus according to the embodiment of the present disclosure, the transmittance by the transparent area TA of each pixel area PA can be increased. Therefore, in the display apparatus according to the embodiment of the present disclosure, the objects located on the lower surface of the device substrate 100 can be clearly recognized by the user through the transparent area TA of each pixel area PA.

The transparent area TA of each pixel area PA can overlap one of the optical lenses OL. For example, each of the optical lenses OL can include first lens regions LA1 overlapping with the sub-pixels SP of each pixel area PA and second lens regions LA2 overlapping with the transparent area TA of each pixel area PA. A cross-section shape of each second lens region LA2 can be the same as a cross-section shape of each first lens region LA1. For example, a width of each second lens region LA2 can be the same as a width of each first lens region LA1. Thus, in the display apparatus according to the embodiment of the present disclosure, a process of arranging and/or forming the optical lenses OL on the pixel areas PA can be simplified.

The insulating layers 110, 120, 130, 140, 150 and 160 stacked on the sub-pixels SP of each pixel area PA, the encapsulation structure 400 and the filter insulating layer 600 can extend onto the transparent area TA of the corresponding pixel area PA. For example, the buffer insulating layer 110, the gate insulating layer 120, the interlayer insulating layer 130, the device passivation layer 140, the planarization layer 150, the bank insulating layer 160, the encapsulation structure 400 and the filter insulating layer 600 can be sequentially stacked on the transparent area TA of each pixel area PA. Thus, in the display apparatus according to the embodiment of the present disclosure, the deformation of the device substrate 100 and/or the optical lenses OL due to a difference in the thickness of the emission areas EA and the transparent area TA in each pixel area PA can be prevented.

The black matrix 510 can be disposed between the emission areas EA and the transparent area TA of each pixel area PA. For example, the black matrix 510 can be disposed outside the emission areas EA and the transparent area TA of each pixel area PA. The emission areas EA and the transparent area TA of each pixel area PA can be surrounded by the black matrix 510. Thus, in the display apparatus according to the embodiment of the present disclosure, the light emitted from the emission areas EA of each pixel area PA toward the transparent area TA of the corresponding pixel area PA can be blocked by the black matrix 510. Therefore, in the display apparatus according to the embodiment of the present disclosure, the objects recognized by the user through the transparent area TA of each pixel area PA can't be distorted and/or deteriorated by the light emitted from the emission areas EA of the corresponding pixel area PA.

A correction structure 710 can be disposed between the filter insulating layer 600 and the optical lenses OL. The correction structure 710 can include a transparent material. The correction structure 710 can include an insulating material. For example, the correction structure 710 can include an organic insulating material and/or an inorganic insulating material. The correction structure 710 can overlap the emission areas EA and the transparent area TA of each pixel area PA. The correction structure 710 can have a constant thickness on the sub-pixels SP of each pixel area PA. For example, an upper surface of the correction structure 710 toward the optical lenses OL can be parallel to a lower surface of the correction structure 710 toward the device substrate 100 on the sub-pixels SP of each pixel area PA. The correction structure 710 can be in direct contact with the filter insulating layer 600 and the optical lenses OL. Thus, in the display apparatus according to the embodiment of the present disclosure, an optical path of the light emitted from the emission area EA of each sub-pixel SP can be sufficiently secured, and the damage of the light-emitting devices 300 and the movement of the optical lenses OL due to the external impact can be prevented.

Curved surfaces 710c of a concave shape overlapping with the transparent areas TA of the pixel areas PA can be disposed at the lower surface of the correction structure 710. For example, the transparent area TA of each pixel area PA can overlap one of the curved surfaces 710c of a concave shape disposed at the lower surface of the correction structure 710. The curved surface 710c having a concave shape of the correction structure 710 can have the same curvature. The curved surface 710c having a concave shape overlapping with the transparent area TA of each pixel area PA can have a greater size than the transparent area TA of the corresponding pixel area PA. The curved surfaces 710c having a concave shape of the correction structure 710 can be spaced apart from the sub-pixels SP of each pixel area PA.

Correcting patterns 720 can be disposed between the filter insulating layer 600 and the curved surfaces 710c having a concave shape of the correction structure 710. The correcting patterns 720 can be in direct contact with the curved surfaces 710c having a concave shape of the correction structure 710. For example, a surface of each correcting pattern 720 toward the optical lenses OL can have a same curvature as the curved surface 710c having a concave shape of the correction structure 710. The correcting patterns 720 can be in direct contact with the filter insulating layer 600. For example, a lower surface of each correcting pattern 720 toward the device substrate 100 can be continuous with the lower surface of the correction structure 710.

The correcting patterns 720 can include a transparent material. The correcting pattern 720 can include an insulating material. For example, each of the correcting patterns 720 can include an organic insulating material and/or an inorganic insulating material. A refractive index of each correcting pattern 720 can be smaller than a refractive index of the correction structure 710. Thus, in the display apparatus according to the embodiment of the present disclosure, the external light Le passing through the transparent area TA of each pixel area PA can be diffused by a difference in the refractive index between each correcting pattern 720 and the correction structure 710. That is, in the display apparatus according to the embodiment of the present disclosure, the curved surfaces 710c having a concave shape, that are at boundaries between the correcting patterns 720 and the correction structure 710 can function as a concave lens, respectively. A portion of the correction structure 710 overlapping with the transparent area TA of each pixel area PA can be defined as a correcting lens CL. For example, in the display apparatus according to the embodiment of the present disclosure, the correcting lenses CL functioning as a concave lens can be disposed between a portion of the filter insulating layer 600 overlapping with the transparent area TA of each pixel area PA and the second lens region LA2 of each optical lens OL.

The external light Le passing through one of the transparent areas TA of the device substrate 100 can be primarily refracted by one of the correcting lenses CL and secondarily refracted by the second lens region LA2 of one of the optical lenses OL. The external light Le passing through each correcting lens CL can be diffused, and the external light Le passing through the second lens region LA2 of each optical lens OL can be condensed. Thus, in the display apparatus according to the embodiment of the present disclosure, the condensing effect of the external light Le can be significantly reduced by the diffusion of the external light Le by each correcting lens CL. The curved surface 710c having a concave shape overlapping with the transparent area TA of each pixel area PA can have a curvature that can offset the condensing of the light passing through the second lens region LA2 of the optical lens OL on the corresponding pixel area PA. For example, the curved surfaces 710c having a concave shape of the correction structure 710 can have a different curvature from surfaces of the optical lenses OL opposite to the device substrate 100. That is, in the display apparatus according to the embodiment of the present disclosure, the refraction of the external light Le by the second lens region LA2 of each optical lens OL can be substantially canceled by the refraction of the external light Le by each correcting lens CL. Therefore, in the display apparatus according to the embodiment of the present disclosure, the objects located on the lower surface of the device substrate 100 can be recognized by the user, without being substantially influenced by the optical lenses OL. That is, in the display apparatus according to the embodiment of the present disclosure, the distortion of the objects located on the lower surface of the device substrate 100 due to the optical lenses OL can be prevented or at least reduced.

Accordingly, the display apparatus according to the embodiment of the present disclosure can include the light-emitting devices 300 on the emission areas EA of the device substrate 100, the encapsulation structure 400 covering the light-emitting devices 300, the optical lenses OL disposed on the encapsulation structure 400, and the correcting lenses CL disposed between the encapsulation structure 400 and the optical lenses OL, wherein the correcting lenses CL can overlap the transparent areas TA of the device substrate 100, and wherein a surface of each correcting lens CL toward the device substrate 100 can have the curved surface 710c of a concave shape. Thus, in the display apparatus according to the embodiment of the present disclosure, the external light Le passing through the transparent areas TA of the device substrate 100 can be provided to the user, without the influence of the optical lenses OL by the correcting lenses CL. Therefore, in the display apparatus according to the embodiment of the present disclosure, the distortion of the objects recognized by the user through the transparent areas TA of the device substrate 100 can be prevented.

And, in the display apparatus according to the embodiment of the present disclosure, the correcting lenses CL can be formed by a different in the refractive index between the correction structure 710 and the correcting patterns 720. Thus, in the display apparatus according to the embodiment of the present disclosure, a process of the correcting lenses CL can be simplified. Therefore, in the display apparatus according to the embodiment of the present disclosure, the production energy can be reduced by the process optimization.

The display apparatus according to the embodiment of the present disclosure is described that the driving circuit DC of each pixel area PA can consist of the first thin film transistor TR1, the second thin film transistor TR2 and the storage capacitor Cst. However, in the display apparatus according to another embodiment of the present disclosure, the driving circuit DC of each pixel area PA can include a driving thin film transistor and at least one switching thin film transistor. For example, in the display apparatus according to another embodiment of the present disclosure, the driving circuit DC of each pixel area PA can further include a third thin film transistor capable of initializing the storage capacitor Cst of the corresponding pixel area PA according to the gate signal. The third thin film transistor of each pixel area PA can include a third semiconductor pattern, a third gate electrode, a third drain electrode and a third source electrode. The third semiconductor pattern of each pixel area PA can include a semiconductor material. The third gate electrode of each pixel area PA can be electrically connected to the corresponding gate line GL. The third drain electrode of each pixel area PA can be electrically connected to an initial line applying an initial signal. The third source electrode of each pixel area PA can be electrically connected to the storage capacitor Cst of the corresponding pixel area PA. Thus, in the display apparatus according to another embodiment of the present disclosure, the degree of freedom in configuring each driving circuit DC can be improved.

In the display apparatus according to the embodiment of the present disclosure, the location and the electric connection of the first drain electrode, the first source electrode, the second drain electrodes 225 and the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

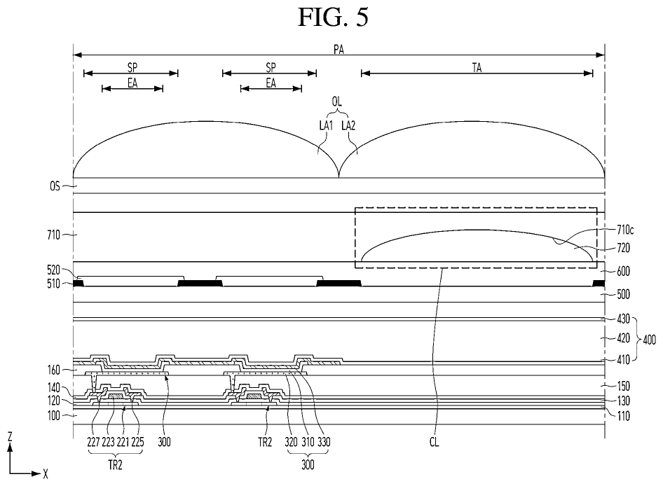

The display apparatus according to the embodiment of the present disclosure is described that the light emitted from the light-emitting device 300 of each sub-pixel SP can display a same color as the light emitted from the light-emitting device 300 of adjacent sub-pixel SP. However, in the display apparatus according to another embodiment of the present disclosure, the light emitted from the light-emitting device 300 of each sub-pixel SP can display a different color from the light emitted from the light-emitting device 300 of adjacent sub-pixel SP. For example, in the display apparatus according to another embodiment of the present disclosure, the light-emitting layer 320 of each sub-pixel SP can be spaced apart from the light-emitting layer 320 of adjacent sub-pixel SP, as shown in FIG. 5. The light-emitting layer 320 of each sub-pixel SP can include a different material from the light-emitting layer 320 of adjacent sub-pixel SP. The light-emitting layer 320 of each sub-pixel SP can have a stacked structure different from the light-emitting layer 320 of adjacent sub-pixel SP. For example, each of the sub-pixels SP can be one of a red sub-pixel displaying the red color, a green sub-pixel displaying the green color, and a blue sub-pixel displaying the blue color, and the light-emitting layer 320 of each sub-pixel SP can include a red emission material generating the red light, a green emission material generating the green light, and a blue emission material generating the blue light according to the color displayed by the corresponding sub-pixel SP. Thus, in the display apparatus according to another embodiment of the present disclosure, the color reproduction of each sub-pixel SP can be improved.

The display apparatus according to the embodiment of the present disclosure is described that the optical lenses OL can be in direct contact with the upper surface of the correction structure 710. However, in the display apparatus according to another embodiment of the present disclosure, the optical lenses OL can be spaced apart from the correction structure 710. For example, in the display apparatus according to another embodiment of the present disclosure, the optical lenses OL can be supported by an optical substrate OS, as shown in FIG. 5. The optical substrate OS can be spaced apart from the correction structure 710. The optical substrate OS can include an insulating material. The optical substrate OS can include a transparent material. For example, the optical substrate OS can include glass or plastic. The optical lenses OL can be formed, regardless of the formation process of the light-emitting devices 300 and the formation process of the correction structure 710. For example, the optical lenses OL formed by a separated process can be physically fixed on the device substrate 100 in which the light-emitting devices 300 and the correction structure 710 are formed. Thus, in the display apparatus according to another embodiment of the present disclosure, the damage of the light-emitting devices 300 due to a process of forming the optical lenses OL can be prevented. And, in the display apparatus according to another embodiment of the present disclosure, the degree of freedom for the material and the formation process of the optical lenses OL can be improved.

The display apparatus according to another embodiment of the present disclosure can include a filter substrate 500 supporting the black matrix 510, the color filters 520, the filter insulating layer 600, the correction structure 710 and the correcting patterns 720. The filter substrate 500 can be spaced apart from the encapsulation structure 400. For example, the black matrix 510, the color filters 520, the filter insulating layer 600, the correction structure 710 and the correcting patterns 720 can be formed, regardless of the formation process of the light-emitting devices 300. The filter substrate 500 can be physically fixed on the device substrate 100 in which the light-emitting devices 300 are formed. Thus, in the display apparatus according to another embodiment of the present disclosure, the damage of the light-emitting devices 300 due to the formation process of the black matrix 510, the color filters 520, the filter insulating layer 600, the correction structure 710 and/or the correcting patterns 720 can be prevented. Therefore, in the display apparatus according to another embodiment of the present disclosure, the damage of the light-emitting devices 300 due to the formation process can be effectively prevented or at least reduced.

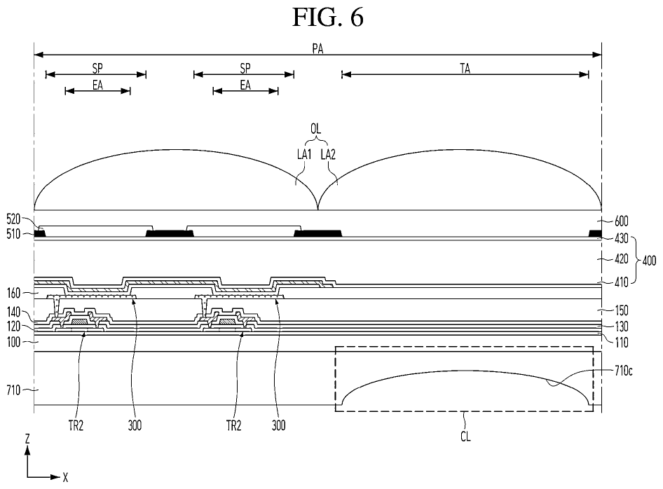

The display apparatus according to the embodiment of the present disclosure is described that the correcting lenses CL can be disposed between the filter insulating layer 600 and the optical lenses OL. However, in the display apparatus according to another embodiment of the present disclosure, the correcting lenses CL can be arranged on various positions. For example, in the display apparatus according to another embodiment of the present disclosure, the correction structure 710 can be disposed on the lower surface of the device substrate 100, as shown in FIG. 6. An upper surface of the correction structure 710 toward the optical lenses OL can be in direct contact with the lower surface of the device substrate 100. A lower surface of each optical lens OL can be direct contact with the filter insulating layer 600. The correcting lenses CL formed by the curved surfaces 710c having a concave shape of the correction structure 710 can overlap the transparent area TA of each pixel area PA. Thus, in the display apparatus according to another embodiment of the present disclosure, the external light primarily refracted by the correcting lenses CL can passes through the transparent areas TA of the device substrate 100. Therefore, in the display apparatus according to another embodiment of the present disclosure, the degree of freedom for the location of the correcting lenses CL to offset the refraction by the second lens region LA2 of each optical lens OL can be improved.

The display apparatus according to the embodiment of the present disclosure is described that the correcting lenses CL can be formed by the difference in the refractive index between the correction structure 710 and the correcting patterns 720. However, in the display apparatus according to another embodiment of the present disclosure, the curved surfaces 710c having a concave shape of the correction structure 710 can be in direct contact with an air. For example, in the display apparatus according to another embodiment of the present disclosure, the curved surfaces 710c having a concave shape of the correction structure 710 can be exposed outside, as shown in FIG. 6. Thus, in the display apparatus according to another embodiment of the present disclosure, each of the correcting lenses CL can be formed by the difference in the refractive index between the correction structure 710 and the air. That is, in the display apparatus according to another embodiment of the present disclosure, a process of forming the correcting patterns 720 can be omitted. Therefore, in the display apparatus according to another embodiment of the present disclosure, the degree of the process efficiency can be minimized or at least reduced, and the distortion of the objects recognized by the user through the transparent areas TA of the device substrate 100 can be prevented or at least reduced. And, in the display apparatus according to another embodiment of the present disclosure, the transmittance of each transparent area TA can be improved.

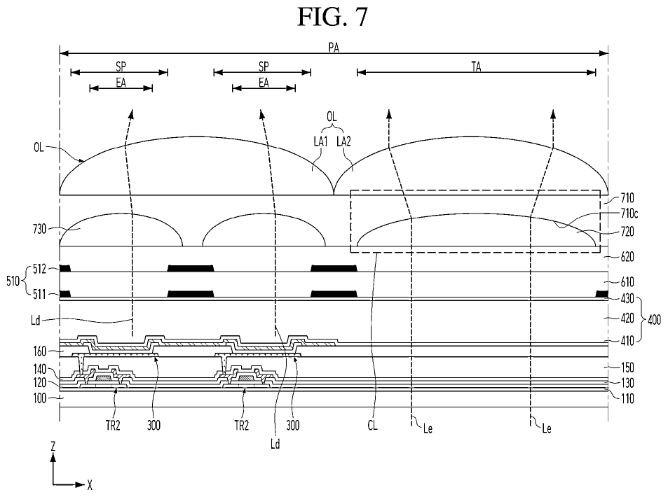

The display apparatus according to the embodiment of the present disclosure is described that the black matrix 510 having a single-layer structure can be disposed on the emission area EA of each sub-pixel SP. However, in the display apparatus according to another embodiment of the present disclosure, the travelling direction of the light emitted by the light-emitting device 300 of each sub-pixel SP can be limited by at least two layer of the black matrix 510. For example, in the display apparatus according to another embodiment of the present disclosure, a first black matrix 511 can be disposed on the encapsulation structure 400, a second black matrix 512 can be disposed on a first filter insulating layer 610 covering the first black matrix 511, and the correction structure 710 and the correcting patterns 720 can be disposed on a second filter insulating layer 620 covering the second black matrix 512, as shown in FIG. 7. Thus, in the display apparatus according to another embodiment of the present disclosure, the travelling direction of the light emitted by the light-emitting device 300 of each sub-pixel SP can be limited by the first black matrix 511 and the second black matrix 512. That is, in the display apparatus according to another embodiment of the present disclosure, a narrow viewing angle can be realized by the black matrix 510 having a multi-layer structure. For example, in the display apparatus according to another embodiment of the present disclosure, the image provided to the user can't be recognized people around the user. And, in the display apparatus according to another embodiment of the present disclosure, the generation of unnecessary images due to the diffusion of light can be prevented. For example, in the display apparatus according to another embodiment of the present disclosure, the repeated generation of the image three-dimensionally recognized by the user by the optical lenses OL can be prevented. Therefore, in the display apparatus according to another embodiment of the present disclosure, the quality of the image provided to the user can be improved.

In the display apparatus according to another embodiment of the present disclosure, pixel lenses 730 can be disposed between the second filter insulating layer 620 and the first lens regions LA1 of the optical lenses OL. Each of the pixel lenses 730 can overlap the emission area EA of one of the sub-pixels SP disposed in each pixel area PA. The pixel lenses 730 can be a convex lens. For example, a surface of each pixel lens 730 opposite to the device substrate 100 can have a convex shape toward the optical lenses OL. Thus, in the display apparatus according to another embodiment of the present disclosure, the light Ld emitted from the light-emitting device 300 of each sub-pixel SP can be primarily condensed by the pixel lens 730 disposed on the corresponding sub-pixel SP, and secondarily condensed by the first lens region LA1 of one of the optical lenses OL. Therefore, in the display apparatus according to another embodiment of the present disclosure, the luminance of the light provided to the user can be improved.

The pixel lenses 730 can be disposed on a same layer as the correcting patterns 720. For example, a lower surface of each pixel lens 730 toward the device substrate 100 can be continuous with the lower surface of the correction structure 710. The lower surface of each pixel lens 730 and the lower surface of each correcting pattern 720 can be in direct contact with the second filter insulating layer 620. A surface of each pixel lens 730 opposite to the device substrate 100 can be in direct contact with the correction structure 710. A refractive index of each pixel lens 730 can be larger than the refractive index of the correction structure 710. Thus, in the display apparatus according to anther embodiment of the present disclosure, a thickness difference due to the pixel lenses 730 can be removed by the correction structure 710. That is, in the display apparatus according to another embodiment of the present disclosure, a process of forming a planarization layer to remove a thickness difference due to the pixel lenses 730 can be omitted. Therefore, in the display apparatus according to another embodiment of the present disclosure, the process efficiency can be improved.

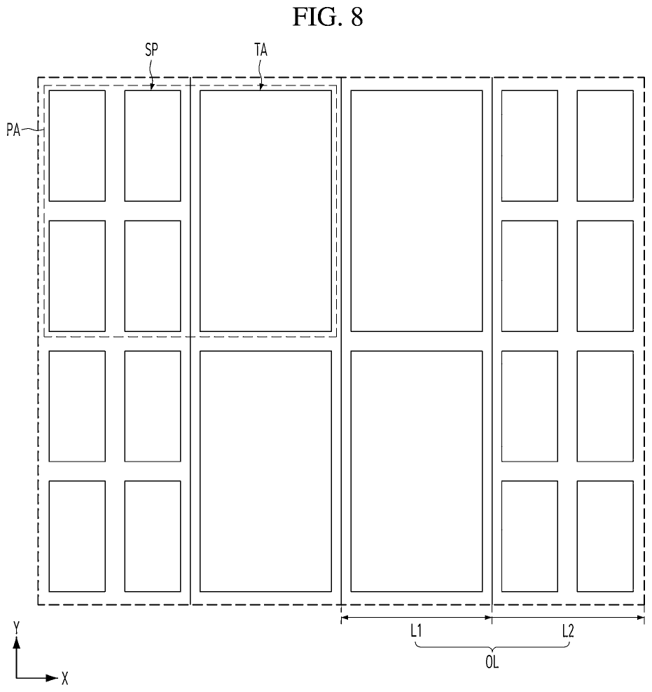

The display apparatus according to the embodiment of the present disclosure is described that the optical lenses OL can extend in a direction inclined with the first direction X and the second direction Y. However, in the display apparatus according to another embodiment of the present disclosure, the optical lenses OL can extend in the first direction X or the second direction Y. For example, in the display apparatus according to another embodiment of the present disclosure, the optical lenses OL can include first lenses L1 overlapping with the sub-pixels SP of each pixel area PA and second lenses L2 overlapping with the transparent area TA of each pixel area PA, as shown in FIG. 8. The second lenses L2 can extend parallel to the first lenses L1. For example, in the display apparatus according to another embodiment of the present disclosure, the first lenses L1 and the second lenses L2 can extend in the second direction Y. Thus, in the display apparatus according to another embodiment of the present disclosure, the distortion of the objects provided to the user through the transparent area TA of each pixel area PA, and the optical lenses OL can be arranged in various locations according to the image provided to the user by using the light emitted from the light-emitting device 300 of each sub-pixel SP. Therefore, in the display apparatus according to another embodiment of the present disclosure, the degree of freedom for the arrangement of the optical lenses OL can be improved.

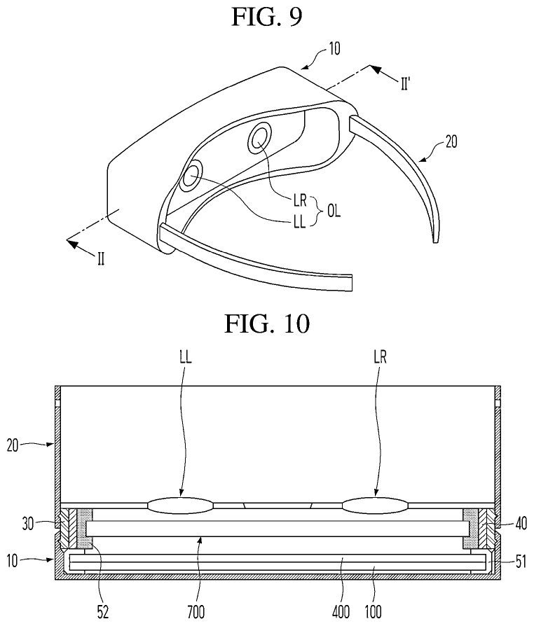

The display apparatus according to the embodiment of the present disclosure can be used in various electric devices. For example, the display apparatus according to the embodiment of the present disclosure can include an image element 10 in which the display panel DP is accommodated, as shown in FIGS. 9 and 10. The image element 10 can be fixed in front of the user's eyes by a mounting element 20. For example, the display apparatus according to the embodiment of the present disclosure can be a head mounted display apparatus (HMD) mounted on the user's head. The mounting element 20 can have a shape, such as a leg of a spectacle frame. For example, the mounting element 20 can have a shape extending in a direction from an edge of the image element 10. The mounting element 20 can be coupled to the image element 10 by a coupling element 30. For example, the coupling element 30 can have a plate shape including a region coupled to the image element 10 and a region coupled to the mounting element 20. The coupling element 30 can be disposed inside the image element 10 and the mounting element 20.

The optical lenses OL can include a left-eye lens LL disposed in front of the user's left eye, and a right-eye lens LR disposed in front of the user's right eye. An empty space can be disposed between the device substrate 100 in which the encapsulation structure 400 is formed and the optical lenses OL. For example, the device substrate 100 in which the encapsulation structure 400 is formed can be disposed close to a first surface of the image element 10, and the left-eye lens LL and the right-eye lens LR can be fixed at a second surface of the image element 10 opposite to the first surface of the image element 10. A gap maintaining element 40 can be disposed inside the coupling element 30 to maintain a space between the optical lenses OL and the device substrate 100 in which the encapsulation structure 400 is formed. The gap maintaining element 40 can be disposed parallel to the coupling element 30. For example, the gap maintaining element 40 can be in direct contact with an inside surface of the coupling element 30.

A correction unit 700 can be disposed between the encapsulation structure 400 and the optical lenses OL. The correction unit 700 can include the correction structure. Thus, in the display apparatus according to the embodiment of the present disclosure, the objects located in front of the user and the image displayed on the objects by the display panel DP can be simultaneously provided to the user, and the distortion of the objects can be prevented. Therefore, in the display apparatus according to the embodiment of the present disclosure, the accidents by blocking the user's field of view and the accidents by the distortion of the objects recognized by the user can be reduced.

A first fixing part 51 to fix the device substrate 100 in which the encapsulation structure 400 is formed and a second fixing part 52 to fix the correction unit 700 can be disposed in the image element 10. The first fixing part 51 can be in direct contact with the image element 10. The second fixing part 52 can be in direct contact with the gap maintaining element 40. The second fixing part 52 can include a region contacting the first fixing part 51. Thus, in the display apparatus according to the embodiment of the present disclosure, the movement of the device substrate 100, the correction unit 700 and the optical lenses OL according to the user's movement can be effectively prevented or at least reduced. Therefore, in the display apparatus according to the embodiment of the present disclosure, the distortion of the objects recognized by the moved user through the transparent area TA of each pixel area PA can be effectively prevented or at least reduced.

The display apparatus according to the embodiment of the present disclosure is described that the mounting element 20 can have a leg shape of the spectacle frame. However, the display apparatus according to another embodiment of the present disclosure can include the mounting element 20 having various shapes. For example, in the display apparatus according to another embodiment of the present disclosure, the mounting element 20 can have a head gear shape surrounding the user's head. Therefore, in the display apparatus according to another embodiment of the present disclosure, the distortion of the objects recognized by the user through the transparent areas TA of the device substrate 100 can be prevented, regardless of the shape of electronic device including the display panel DP.

In the result, the display apparatus according to the embodiments of the present disclosure can comprise the light-emitting device disposed on the emission area of the device substrate, the correcting lenses overlapping with the transparent area of the device substrate and at least one optical lens disposed on the light-emitting device and the correcting lens, wherein the correcting lens can have a curved surface having a different shape from the at least one optical lens. That is, in the display apparatus according to the embodiments of the present disclosure, the external light passing through the transparent area of the device substrate can be provided to the user by passing through the correcting lens and the at least one optical lens. Thus, in the display apparatus according to the embodiments of the present disclosure, the refraction of the external light due to the at least one optical lens can be compensated by the correction lens. Thereby, in the display apparatus according to the embodiments of the present disclosure, the distortion of the objects recognized by the user through the transparent area of the device substrate can be prevented or at least reduced. And, in the display apparatus according to the embodiments of the present disclosure, the production energy can be reduced by the process optimization.

What is claimed is:

1. A display apparatus comprising:
a device substrate;
a light-emitting device on an emission area of the device substrate;
a corrective lens overlapping with a transparent area of the device substrate; and
at least one optical lens on the light-emitting device and the corrective lens,
wherein a surface of the corrective lens opposite to the at least one optical lens has a concave curved shape.

2. The display apparatus according to claim 1, wherein a surface of the at least one optical lens opposite to the device substrate has a convex curved shape.

3. The display apparatus according to claim 1, wherein the device substrate includes a first surface toward the light-emitting device and a second surface opposite to the first surface, and the corrective lens is on the second surface of the device substrate.

4. The display apparatus according to claim 3, wherein a surface of the corrective lens toward the at least one optical lens is in contact with the second surface of the device substrate.

5. The display apparatus according to claim 3, further comprising:
a filter insulating layer between the light-emitting device and the at least one optical lens, the filter insulating layer extending onto the transparent area; and
a color filter between the light-emitting device and the filter insulating layer, the color filter overlapping with the emission area,
wherein the at least one optical lens is in contact with the filter insulating layer.

6. The display apparatus according to claim 1, wherein the at least one optical lens includes a first lens region overlapping with the emission area and a second lens region overlapping with the transparent area, and a width of the second lens region is a same as a width of the first lens region.

7. A display apparatus comprising:
a device substrate including a plurality of pixel areas;
light-emitting devices, each of the light-emitting devices on an emission area of each of the plurality of pixel areas;
a correction structure on the device substrate, the correction structure including curved surfaces of a concave shape overlapping a transparent area of each of the plurality of pixel areas; and
at least one optical lens on the light-emitting devices and the correction structure,
wherein the correction structure includes a first surface toward the at least one optical lens and a second surface opposite to the first surface, and the curved surfaces of the concave shape are at the second surface of the correction structure.

8. The display apparatus according to claim 7, wherein a surface of the at least one optical lens has a curved surface of a convex shape, and the curved surface of the convex shape has a different curvature from the curved surface of the concave shape.

9. The display apparatus according to claim 7, further comprising:
an encapsulation structure on the device substrate, the encapsulation structure covering the light-emitting devices,
wherein the correction structure is between the encapsulation structure and the at least one optical lens.

10. The display apparatus according to claim 9, wherein the correction structure extends onto the emission area of each of the plurality pixel areas.

11. The display apparatus according to claim 9, further comprising:
corrective patterns between the encapsulation structure and the correction structure, the corrective patterns contacting the curved surfaces of the concave shape,
wherein a refractive index of each corrective pattern is smaller than a refractive index of the correction structure.

12. The display apparatus according to claim 11, a surface of each corrective pattern toward the encapsulation structure is continuously with a surface of the correction structure toward the encapsulation structure.

13. The display apparatus according to claim 11, further comprising:
pixel lenses between the encapsulation structure and the correction structure, each of the pixel lenses overlapping with the emission area of each of the plurality pixel areas,
wherein a surface of each pixel lens toward the at least one optical lens has a curved surface of a convex shape.

14. The display apparatus according to claim 13, wherein the surface of each of the plurality pixel areas toward the at least one optical lens is in contact with the correction structure, and a refractive index of the correction structure is smaller than a refractive index of each pixel lens.

15. The display apparatus according to claim 13, wherein a surface of each pixel lens toward the encapsulation structure is continuously with a surface of the correction structure toward the encapsulation structure.
